(19) United States
(12) Patent Application Publication
(10) Pub. No.: US 2017/0186637 A1
(43) Pub. Date: Jun. 29, 2017

(54) WAFER CONTAINER FOR RECEIVING HORIZONTALLY ARRANGED WAFERS

(71) Applicant: SAMSUNG ELECTRONICS CO., LTD., SUWON-SI (KR)

(72) Inventors: HYUN-HO CHO, SUWON-SI (KR); DONG-YEON KIM, HWASEONG-SI (KR); HYEOG-KI KIM, HWASEONG-SI (KR); JUNG-HUN NAM, SEOUL (KR); JIN-HO KIM, HWASEONG-SI (KR)

(21) Appl. No.: 15/261,698

(22) Filed: Sep. 9, 2016

(30) Foreign Application Priority Data
Dec. 24, 2015 (KR) 10-2015-0186131

(51) Int. Cl. H01L 21/673

(52) U.S. Cl. CPC H01L 21/67376; H01L 21/67373

(57) ABSTRACT

A wafer container includes a base, a guide, a cover, a locking member and a sealing member. The base includes an installing surface thereon. The guide is disposed on the installing surface of the base. The guide is configured to confine a plurality of wafers horizontally stacked upon the installing surface of the base. The cover is configured to cover the installing surface. The locking member is configured to lock the cover to the base. The sealing member is configured to create an air-tight seal between the locking member and the guide.

### CROSS-REFERENCE TO RELATED APPLICATIONS

This application claims priority under 35 U.S.C. §119 to Korean Patent Application No. 10-2015-0186131, filed on Dec. 24, 2015 in the Korean Intellectual Property Office, the contents of which are herein incorporated by reference in their entirety.

### TECHNICAL FIELD

The described technology relates to a wafer container, and more particularly, to a wafer container for receiving horizontally arranged wafers.

### DISCUSSION OF RELATED ART

In fabricating semiconductors, there is frequently a need to store semiconductor wafers in a manner that leaves the wafers protected from possible contamination. Generally, a wafer container may include a base, a cover and a locking member. A plurality of guides may be formed on an upper surface of the base to define a space where wafers may be received and supported. The cover may be configured to cover the base and protect the wafer. The locking member may be configured to lock the cover to the base.

When the cover is locked to the base, a gap may be formed between the base and the cover. Further, the locking member may have its own gap. Air, which may include contaminants, may infiltrate into the receiving space of the wafer container through the aforementioned gaps to contaminate the wafers.

### SUMMARY

Exemplary embodiments of the present invention provide a wafer container that might suppress air infiltration.

According to an exemplary embodiment of the present invention, a wafer container is provided. The wafer container includes a base, a guide, a cover, a locking member and a sealing member. The base includes an installing surface thereon. The guide is disposed on the installing surface of the base. The guide is configured to confine a plurality of wafers horizontally stacked upon the installing surface of the base. The cover is configured to cover the installing surface. The locking member is configured to lock the cover to the base. The sealing member is configured to create an air-tight seal between the locking member and the guide.

The sealing member may include a sealing screen. The sealing screen may be configured to surround the guide and contact the cover and the installing surface. The sealing screen may be integrally formed with an inner surface of the cover. The base may further include a sealing groove. The sealing groove may be configured to receive the sealing screen. The sealing member may further include a sealing pad. The sealing pad may be attached to a lower end of the sealing screen. The sealing screen may be integrally formed with the installing surface of the base. The cover may further include a sealing groove. The sealing groove may be configured to receive the sealing screen. The sealing member may further include a sealing pad. The sealing pad may be attached to an upper end of the sealing screen.

The wafer container may further include a gasket. The gasket may be disposed between the guide and the locking member. The gasket may contact the sealing member. The gasket may include a sealing groove. The sealing groove may be configured to receive the sealing member. The gasket may further include a fixing groove. The fixing groove may be configured to receive a fixing protrusion disposed on an outer surface of the guide. The fixing groove may be configured to receive a fixing protrusion disposed on the installing surface of the base.

The locking member may include at least one locking plate. The locking plate may be disposed on the installing surface of the base. The locking plate may include a locking protrusion. The locking member may also include a locking groove. The locking groove may be disposed on the cover. The locking groove may be configured to receive the locking protrusion.

According to an exemplary embodiment of the present invention, a wafer container is provided. The wafer container includes a base, a cover and a gasket. The base includes an installing surface, a plurality of guides and a plurality of locking plates. The guides vertically extend from the installing surface in a circumferential direction. The locking plates vertically extend from a portion of the installing surface beyond the guides with respect to a center of the installing surface. The locking plates are arranged in the circumferential direction of the installing surface. The locking plates include a locking protrusion. The cover includes a sealing screen. The sealing screen is disposed between the guides and the locking plates. The sealing screen contacts an edge portion of the installing surface of the base. The cover also includes a locking groove. The locking groove is configured to receive the locking protrusion. The gasket is detachably attached to the base. The gasket contacts the sealing screen.

The cover may further include a sealing pad. The sealing pad may be attached to a lower end of the sealing screen. The base may further include a sealing groove. The sealing groove may be configured to receive the sealing pad. The base may further include a fixing groove. The fixing groove may be formed on the installing surface. The gasket may include a fixing protrusion. The fixing protrusion may be configured to be received by the fixing groove.

According to an exemplary embodiment of the present invention, a wafer container is provided. The wafer container includes a base, a guide, a cover, a locking member, and a sealing member. The base includes an installing surface thereon. The guide is disposed on the installing surface of the base. The guide is configured to contain a plurality of wafers horizontally stacked on the installing surface. The cover is configured to cover the installing surface. The locking member is configured to lock the cover to the base. The sealing member includes a sealing screen. The sealing member is configured to create an air-tight seal between the locking member and the guide. The sealing screen is integrally formed with the installing surface. The sealing screen is configured to surround the guide and contact the cover and the installing surface.

The cover may further include a sealing groove. The sealing groove may be configured to receive the sealing screen. The sealing member may further include a sealing pad. The sealing pad may be attached to an upper end of the sealing screen.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is an exploded perspective view illustrating a wafer container according to an exemplary embodiment of the present invention;

FIG. 2 is a cross-sectional view illustrating a wafer container of FIG. 1 according to an exemplary embodiment of the present invention;

FIG. 3 is an exploded perspective view illustrating a wafer container according to an exemplary embodiment of the present invention;

FIG. 4 is a cross-sectional view illustrating a wafer container of FIG. 3 according to an exemplary embodiment of the present invention;

FIG. 5 is an exploded perspective view illustrating a wafer container according to an exemplary embodiment of the present invention;

FIG. 6 is a cross-sectional view illustrating a wafer container of FIG. 5 according to an exemplary embodiment of the present invention;

FIG. 7 is an exploded perspective view illustrating a wafer container according to an exemplary embodiment of the present invention; and

FIG. 8 is a cross-sectional view illustrating a wafer container of FIG. 7 according to an exemplary embodiment of the present invention.

### DETAILED DESCRIPTION OF THE EMBODIMENTS

Exemplary embodiments of the present invention will be described more fully herein with reference to the accompanying drawings. Embodiments of the present invention may, however, encompass many different forms and should therefore not be construed as limited to the exemplary embodiments as set forth herein.

In the drawings, the sizes and relative sizes of layers and regions may be exaggerated for clarity. Like numerals may refer to like elements throughout the figures and disclosure and redundant explanations may be omitted.

It will be understood that when an element or layer is referred to as being “on,” “connected to” or “coupled to” another element or layer, it can be directly on, connected or coupled to the other element or layer or intervening elements or layers may be present.

Spatially relative terms, such as “beneath,” “below,” “lower,” “above,” “upper” and the like, may be used herein for ease of description to describe one element or feature in relation to another element(s) or feature(s) as illustrated in the drawings. It will be understood that the spatially relative terms are intended to encompass different orientations of the device in use or operation in addition to the orientation as illustrated in the drawings.

Exemplary embodiments of the present invention will be described below in more detail with reference to the accompanying drawings.

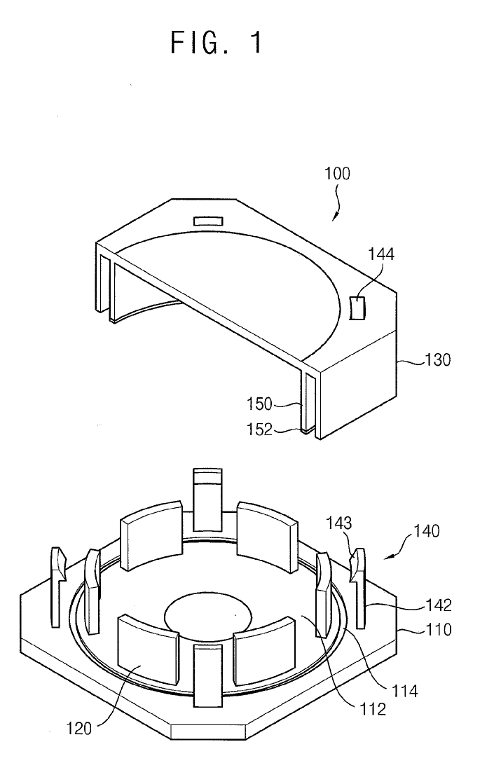

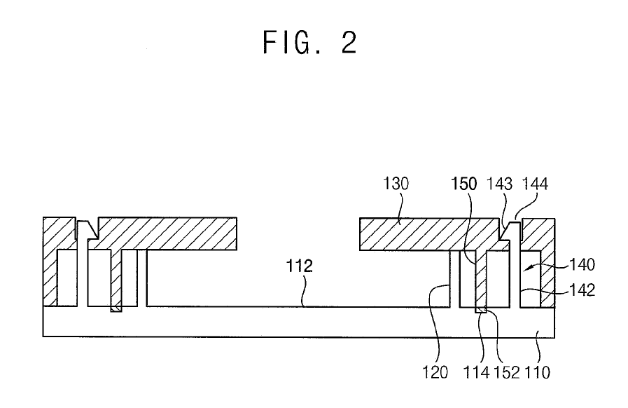

FIG. 1 is an exploded perspective view illustrating a wafer container according to an exemplary embodiment of the present invention. FIG. 2 is a cross-sectional view illustrating a wafer container of FIG. 1 according to an exemplary embodiment of the present invention.

Referring to FIGS. 1 and 2, a wafer container 100 may include a base 110, a plurality of guides 120, a cover 130, a locking member 140 and a sealing member.

The base 110 may include an installing surface 112. A plurality of wafers may be placed on the installing surface 112. The wafers may be horizontally stacked on the installing surface 112. The installing surface 112 may correspond to an upper surface of the base 110. The base 110 may be formed, at least in part, of a plastic material.

The guides 120 may be arranged on the installing surface 112 of the base 110. The arrangement of the guides 120 may define a receiving space within the wafer container 100. Wafers may be received within the receiving space, for example, by placing a first wafer down upon the installing surface 112 and then stacking additional wafers on the first wafer. The guides 120 may be arranged on the installing surface 112 in a circumferential direction around the base 110. Thus, a radius from a center point of the installing surface 112 to the guides 120 may be greater than a radius of each of the wafers. The guides 120 may vertically extend from the installing surface 112. The guides 120 may be integrally formed with the base 110. Alternatively, the guides 120 may be a separate parts attached to the installing surface 112 of the base 110. Further, the guides 120 may be arranged in a rectangular shape, for example, where rectangular wafers are to be received.

FIG. 1 illustrates a portion of the cover 130. Another portion of the cover 130 may be shaped substantially the same as the portion of the cover 130 illustrated in FIG. 1. The cover 130 may be configured to cover the installing surface 112 of the base 110. The cover 130 may include a lower end. The lower end of the cover 130 may be configured to contact an edge portion of the installing surface 112. A gap may be formed between the lower end of the cover 130 and the edge portion of the installing surface 112. The cover 130 may define the receiving space together with the guides 120. Thus, the cover 130 may include a center point substantially corresponding to a center point of the base 110. The cover 130 may be formed from a material substantially the same as that of the base 110. Accordingly, the cover 130 may include a plastic material.

The locking member 140 may be configured to lock the cover 130 to the base 110. The locking member 140 may include a plurality of locking plates 142 that are attached to the base 110. The locking member 140 may further include a plurality of locking grooves 144 that are built into the cover 130.

The locking plates 142 may be arranged on a portion of the installing surface 112 outside the guides 120. The locking plates 142 may be arranged on the portion of the installing surface 112 outside the guides 120 in the circumferential direction of the base 110. Thus, the locking plates 142 may be spaced apart from the guides 120. Alternatively, the locking plates 142 may be arranged in a rectangular shape. The locking plates 142 may vertically extend from the installing surface 112. The locking plates 142 may be integrally formed with the base 110. Alternatively, the locking plates 142 may be separate parts attached to the installing surface 112 of the base 110. Each of the locking plates 142 may include a locking protrusion 143. The locking protrusion 143 may be formed at an upper portion of the locking plate 142. The locking protrusion 143 may be formed on an inner surface of the upper portion of the locking plate 142. Alternatively, the locking protrusion 143 may be formed on an outer surface of the upper portion of the locking plate 142.

The locking grooves 144 may be formed on the cover 130. Since the locking plates 142 may be arranged in the circumferential direction of the base 110, the locking grooves 144 may also be arranged in a circumferential direction of the cover 130. The locking protrusions 143 may be inserted into the locking grooves 144. Gaps may be formed between the locking protrusions 143 and the locking grooves 144.

The sealing member may be configured to seal the gaps between the guides 120 and the locking plates 142 and to thereby prevent air from passing therethrough. Therefore, the sealing member may be configured to suppress air from infiltrating into the receiving space through the gaps between the lower end of the cover 130 and the gaps between the locking protrusions 143 and the locking grooves 144. The sealing member may include a sealing screen 150. The sealing member may also include a sealing pad 152.

The sealing screen 150 may vertically extend from an inner surface of the cover 130 substantially toward a space between the guides 120 and the locking plates 142. The sealing screen 150 may be integrally formed with the cover 130. Alternatively, the sealing screen 150 may be a separate part attached to the cover 130. The sealing screen 150 may be configured to surround the guides 120. For example, the sealing screen 150 may be shaped in an annular shape. Alternatively, the sealing screen 150 may be shaped in a rectangular shape.

The sealing pad 152 may be attached to a lower end of the sealing screen 150. The suiting pad 152 may be configured to contact the portion of the installing surface 112 between the guides 120 and the locking plates 142. The sealing pad 152 may include a flexible material. For example, the sealing pad 152 may include a rubber such as an elastomer.

The base 110 may include a sealing groove 114. The sealing pad 152 may be inserted into the sealing groove 114 of the base 110. The sealing groove 114 may be formed on the installing surface 112 in the circumferential direction of the base 110.

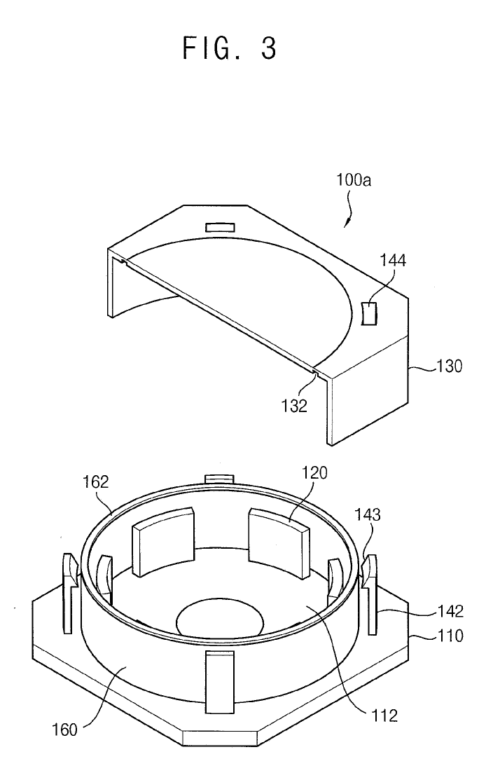

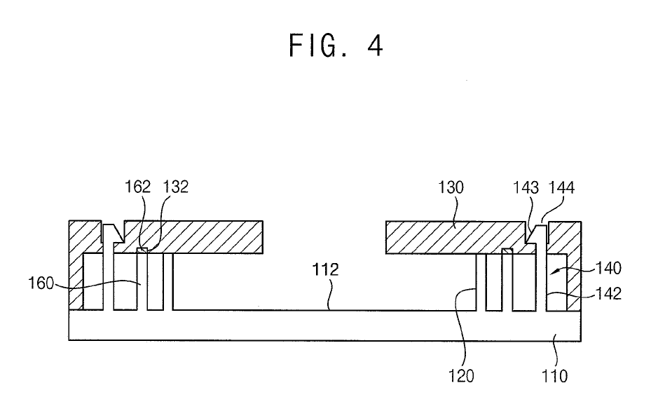

FIG. 3 is an exploded perspective view illustrating a wafer container according to an exemplary embodiment of the present invention. FIG. 4 is a cross-sectional view illustrating a wafer container of FIG. 3 according to an exemplary embodiment of the present invention.

A wafer container 100a may include elements substantially the same as those of the wafer container 100 illustrated in FIGS. 1 and 2. However, the wafer container 100a may include a sealing member that differs from the sealing member of the wafer container 100 illustrated in FIGS. 1 and 2.

Referring to FIGS. 3 and 4, the sealing member may include a sealing screen 160. The sealing member may also include a sealing pad 162.

The sealing screen 160 may vertically extend from a portion of the installing surface 112 between the guides 120 and the locking plates 142. The sealing screen 160 may be integrally formed with the base 110. Alternatively, the sealing screen 160 may be a separate part attached to the base 110. The sealing screen 160 may be configured to surround the guides 120. For example, the sealing screen 160 may have an annular shape. Alternatively, the sealing screen 160 may have a rectangular shape.

The sealing pad 162 may be attached to an upper end of the sealing screen 160. The sealing pad 162 may be configured to contact the inner surface of the cover 130. The sealing pad 162 may include a flexible material. For example, the sealing pad 162 may include a rubber such as an elastomer.

The cover 130 may include a sealing groove 132. The scaling pad 162 may be inserted into the sealing groove 132. The sealing groove 132 may be formed on the inner surface of the cover 130 in the circumferential direction of the cover 130.

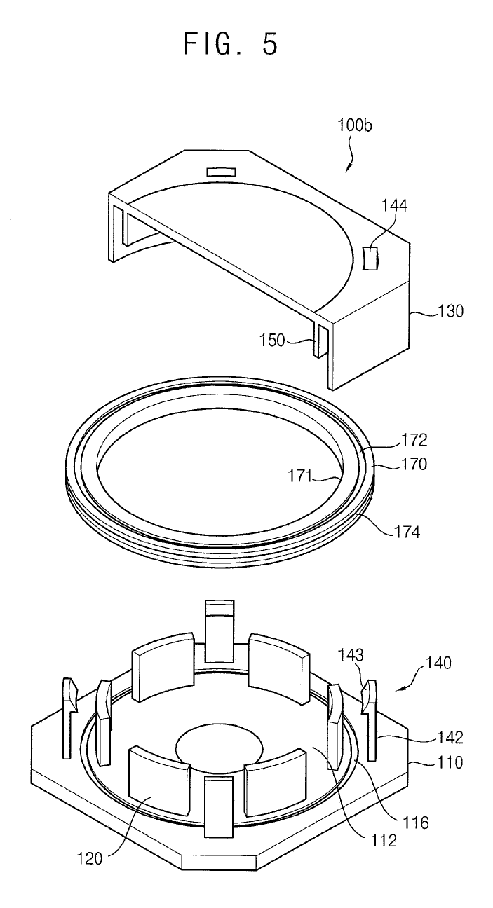

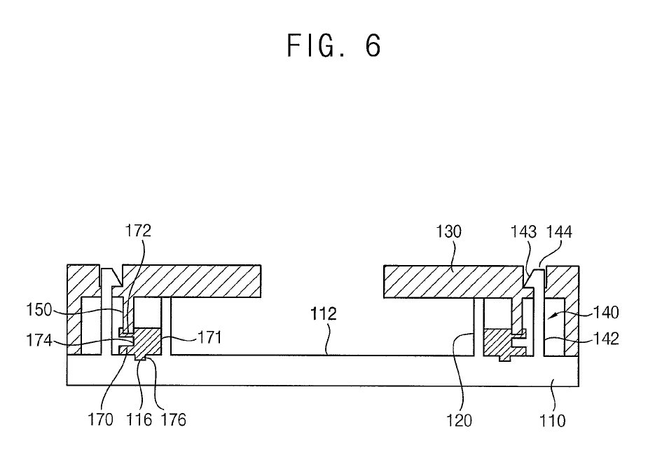

FIG. 5 is an exploded perspective view illustrating a wafer container according to an exemplary embodiment of the present invention. FIG. 6 is a crass-sectional view illustrating a wafer container of FIG. 5 according to an exemplary embodiment of the present invention.

A wafer container 100b may include elements substantially the same as those of a wafer container 100 illustrated in FIGS. 1-2 and a wafer container 100a illustrated in FIGS. 3-4. However, a wafer container 100b as illustrated in FIGS. 5 and 6 may further include a gasket.

Referring to FIGS. 5 and 6, a gasket 170 may be arranged between the guides 120 and the locking plates 142. The gasket 170 may be configured to contact a lower end of the sealing screen 150. The gasket 170 may be attached to the installing surface 112 of the base 110. The gasket 170 may include a flexible material. For example, the gasket 170 may include a rubber such as an elastomer.

The gasket 170 may include supporting protrusions 171. The supporting protrusions 171 may be formed on an inner surface of the gasket 170. The supporting protrusions 171 may be configured to contact both side surfaces of the guides 120. As such, the guides 120 may support the gasket 170.

The gasket 170 may include a sealing groove 172. The sealing groove 172 may be formed on an upper surface of the gasket 170. The lower end of the sealing screen 150 may be inserted into the sealing groove 172.

The gasket 170 may include a receiving groove 174. The receiving groove 174 may be formed on an outer surface of the gasket 170. When the lower end of the sealing screen 150 inserted into the sealing groove 172 presses the gasket 170, the gasket 170 may be inserted into the receiving groove 174. Accordingly, adhesion between the lower end of the sealing screen 150 and an inner surface of the sealing groove 172 may be increased.

The gasket 170 may include a fixing protrusion 176. The fixing protrusion 176 may be formed on a lower surface of the gasket 170. A fixing groove 116 may be formed on the installing surface 112 of the base 110. The fixing protrusion 176 may be inserted into the fixing groove 116. The gasket 170 may be combined with the base 110 by inserting the fixing protrusion 176 into the fixing groove 116.

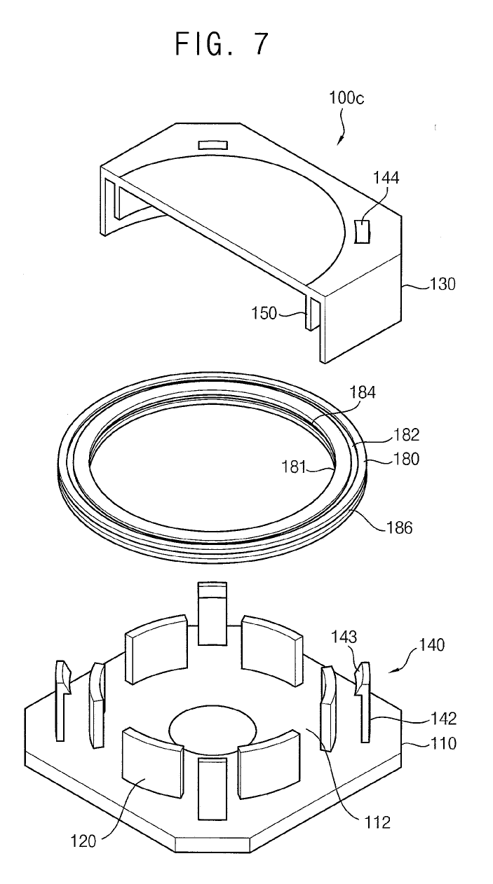

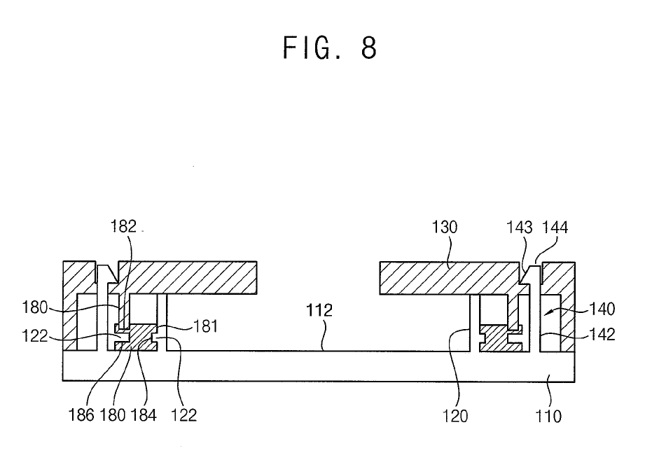

FIG. 7 is an exploded perspective view illustrating a wafer container according to an exemplary embodiment of the present invention. FIG. 8 is a cross-sectional view illustrating a wafer container of FIG. 7 according to an exemplary embodiment of the present invention.

A wafer container 100c may include elements substantially the same as those of a wafer container 100b illustrated in FIGS. 5 and 6. However, the wafer container 100c may include a gasket that differs from the gasket of the wafer container 100b illustrated in FIGS, 5 and 6.

Referring to FIGS. 7 and 8, a gasket 180 may include supporting protrusions 181. The supporting protrusions 181 may be formed on an inner surface of the gasket 180. The supporting protrusions 181 may be configured to contact both side surfaces of the guides 120. As such, the guides 120 may support the gasket 180.

The gasket 180 may include a sealing groove 182. The sealing groove 182 may be formed on an upper surface of the gasket 180. A lower end of the sealing screen 150 may be inserted into the sealing groove 182.

The gasket 180 may include a receiving groove 184. The receiving groove 184 may be formed on an outer surface of the gasket 180. The lower end of the sealing screen 150 may be inserted into the sealing groove 182 and may press the gasket 180. Therefore, the gasket 180 may be inserted into the receiving groove 184 and may increase adhesion between the lower end of the sealing screen 150 and an inner surface of the sealing groove 182.

The gasket 180 may include a fixing groove 186. The fixing groove 186 may be formed on an inner surface of the gasket 180. A fixing protrusion 122 may be formed on the outer surface of the guides 120. The fixing protrusion 122 may be inserted into the fixing groove 186. The gasket 180 may be combined with the guide 120 by inserting the fixing protrusion 122 into the fixing groove 186.

The sealing member may be configured to seal a gap between the guides 120 and the locking member 140. Accordingly, air may be prevented from infiltrating into the receiving space in the guides 120. Thus, contamination of the wafers in the receiving space may be suppressed.

The foregoing is illustrative of exemplary embodiments of the present invention and is not to be construed as limiting thereof Although a few exemplary embodiments have been described herein, those skilled in the art will readily appreciate that many modifications are possible in the exemplary embodiments without materially departing from the novel teachings and advantages of the present inventive concept. Accordingly, all such modifications are intended to be included within the scope of the embodiments of the present invention.

What is claimed:

1. A wafer container comprising:
a base including an installing surface thereon;
a guide disposed on the installing surface of the base and configured to confine a plurality of wafers, horizontally stacked upon the installing surface of the base;
a cover configured to cover the installing surface;
a locking member configured to lock the cover to the base; and
a sealing member configured to create an air-tight seal between the locking member and the guide.

2. The wafer container of claim 1, wherein the sealing member comprises a sealing screen configured to surround the guide and contact the cover and the installing surface.

3. The wafer container of claim 2, wherein the sealing screen is integrally formed with an inner surface of the cover.

4. The wafer container of claim 3, wherein the base further comprises a sealing groove configured to receive the sealing screen.

5. The wafer container of claim 3, wherein the sealing member further comprises a sealing pad attached to a lower end of the sealing screen.

6. The wafer container of claim 2, wherein the sealing screen is integrally formed with the installing surface of the base.

7. The wafer container of claim 6, wherein the cover further comprises a sealing groove configured to receive the sealing screen.

8. The wafer container of claim 6, wherein the sealing member further comprises a sealing pad attached to an upper end of the sealing screen.

9. The wafer container of claim 1, further comprising a gasket disposed between the guide and the locking member, wherein the gasket contacts the sealing member.

10. The wafer container of claim 9, wherein the gasket comprises a sealing groove configured to receive the sealing member.

11. The wafer container of claim 9, wherein the gasket further comprises a fixing groove configured to receive a fixing protrusion disposed on an outer surface of the guide.

12. The wafer container of claim 9, wherein the gasket further comprises a fixing groove configured to receive a fixing protrusion disposed on the installing surface of the base.

13. The wafer container of claim 1, wherein the locking member comprises:
at least one locking plate disposed on the installing surface of the base, the locking plate including a locking protrusion; and
a locking groove disposed on the cover and configured to receive the locking protrusion.

14. A wafer container comprising:
a base including an installing surface;
a plurality of guides vertically extended from the installing surface in a circumferential direction;
a plurality of locking plates vertically extended from a portion of the installing surface beyond the guides, with respect to a center of the installing surface, the plurality of locking plates being arranged in the circumferential direction of the installing surface and including a locking protrusion;
a cover including a sealing screen that is disposed between the guides and the locking plates and contacts an edge portion of the installing surface of the base, and a locking groove configured to receive the locking protrusion; and
a gasket detachably attached to the base and contacting the sealing screen.

15. The wafer container of claim 14, wherein the cover further comprises a sealing pad attached to a lower end of the sealing screen.

16. The wafer container of claim 14, wherein the base further comprises a sealing groove configured to receive the sealing pad and a fixing groove formed on the installing surface.

17. The wafer container of claim 16, wherein the gasket comprises a fixing protrusion configured to be received by the fixing groove.

18. A wafer container comprising:
a base including an installing surface thereon;
a guide disposed on the installing surface of the base and configured to contain a plurality of wafers horizontally stacked on the installing surface;
a cover configured to cover the installing surface;
a locking member configured to lock the cover to the base; and
a sealing member including a sealing screen,
wherein the sealing member is configured to create an air-tight seal between the locking member and the guide, and
wherein the sealing screen is integrally formed with the installing surface and is configured to surround the guide and contact the cover and the installing surface.

19. The container of claim 18, wherein the cover further comprises a sealing groove configured to receive the sealing screen.

20. The container of claim 18, wherein the sealing member further comprises a sealing pad attached to an upper end of the sealing screen.
